(19) United States
(12) Patent Application Publication
(10) Pub. No.: US 2021/0031192 A1
(43) Pub. Date: Feb. 4, 2021

(54) MICROFLUIDIC DEVICES

(71) Applicant: HEWLETT-PACKARD DEVELOPMENT COMPANY, L.P., SPRING, TX (US)

(72) Inventors: Pavel Kornilovich, Corvallis, OR (US); Ross Warner, Corvallis, OR (US); Alexander Govyadinov, Corvallis, OR (US)

(73) Assignee: HEWLETT-PACKARD DEVELOPMENT COMPANY, L.P., SPRING, TX (US)

(21) Appl. No.: 16/768,857

(22) PCT Filed: Mar. 12, 2018
(86) PCT No.: PCT/US2018/022012

§ 371 Date: Jun. 1, 2020

(51) Int. Cl. B01L 3/00

(52) U.S. Cl. CPC B01L 3/502707; B01L 2200/12; B01L 2200/0684; B01L 2200/16; B01L 2400/0406

(57) ABSTRACT

A microfluidic device may include a die package. The die package may include at least on fluidic die and an overmold material overmolding the fluidic die. The microfluidic device may also include a mesofluidic plate coupled to the die package. The mesofluidic plate includes at least one mesofluidic channel formed therein to fluidically couple the fluidic die.

### BACKGROUND

Microfluidics involves the study of small volumes of fluid and how to manipulate, control, and use such small volumes of fluid in various systems and devices, such as microfluidic chips. In some instances, microfluidic chips may be used in the medical and biological fields to evaluate fluids and their components. Microfluidic devices may be used to move picoliter or microliter amounts of fluids within a very small package. In some instances, these devices may be referred to as lab-on-chip devices, and may be used in, for example, biomedical applications to react small amounts of reagents for analysis. Microfluidic devices are used when low volumes are to be processed to achieve multiplexing, automation, and high-throughput screening.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a cross-sectional block diagram of a microfluidic device, according to an example of the principles described herein.

FIG. 2 is a cross-sectional block diagram of a microfluidic device, according to another example of the principles described herein.

FIG. 3 is an exploded, isometric view of a microfluidic device, according to an example of the principles described herein.

FIG. 4 is an isometric view of a microfluidic device, according to an example of the principles described herein.

FIG. 5 is a cross-sectional view of a microfluidic device, according to an example of the principles described herein.

FIG. 6 is a bottom view of a microfluidic device, according to an example of the principles described herein.

FIG. 7 is an exploded, isometric view of a microfluidic device, according to another example of the principles described herein.

FIG. 8 is a cross-sectional view of a microfluidic device, according to an example of the principles described herein.

FIG. 9 is a bottom view of a microfluidic device, according to another example of the principles described herein.

FIG. 10 is a flowchart showing a method of fluidic transport, according to an example of the principles described herein.

FIG. 11 is a flowchart showing a method of fluidic transport, according to another example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

In biomedical applications of microfluidics (MF), various fluids and analytes such as, for example, bio-samples, buffers, biological cells, deoxyribonucleic acid (DNA), viruses, and other biological objects and reagents may undergo multiple processing operations such as reactions with other reagents, lysing, mixing, filtration, dilution, separation, heating, and other chemical processes for biological and chemical analysis purposes. These processes may be performed using microfluidic chips made from, for example, silicon, SU8, and other materials that are embedded or molded into a moldable material such as an epoxy mold compound (EMC). One way a microfluidic device may be manufactured is by coupling a single piece of silicon to an SU8 layer of material and use SU8 photolithography to form interconnects between portions of the microfluidic device. This approach, however, is relatively more expensive than other solutions as the silicon layer and the manufacture of the SU8 layer are expensive. Similarly, expensive is the use of backside channels made in silicon on insulator (SOI) wafers.

Another possible method of manufacturing a microfluidic device is by forming mesofluidic interconnects embedded in an overmold material. Although it is possible to form these types of mesofluidic interconnects within the overmold, it is difficult to do so, and moving a fluid in and out of this type of microfluidic device uses special means to pump the fluid against gravity, which complicates the design and increases the expense of the microfluidic device. Further, an SU8 layer may be coupled to the face of a plurality of fluidic die thereby linking different fluidic die fluidically. However, this approach uses very tight tolerances for a between the fluidic die and SU8 layer. The misalignment is to be on the order of a silicon/SU8 feature size (i.e., less than 5 μm), otherwise, features of the fluidic die such as thermal-ejection elements will not be aligned with their respective nozzles and channels. Such tolerances are possible but very challenging, and expensive to manufacture.

Examples described herein provide a microfluidic device. The microfluidic device may include a die package. The die package may include at least one fluidic die and an overmold material overmolding the fluidic die. The microfluidic device may also include a mesofluidic plate coupled to the die package. The mesofluidic plate includes at least one mesofluidic channel formed therein to fluidically couple the fluidic die.

At least one fluidic die of the microfluidic device may include a silicon layer, a fluid feed hole defined in the silicon layer, a nozzle layer coupled to the silicon layer, fluid ejection nozzles formed in the nozzle layer, and a fluid chamber formed in the nozzle layer. The fluid chamber fluidically couples the fluid feed hole to the fluid ejection nozzles. The fluidic die may also include an actuator within the fluid chamber to eject fluid from the fluidic die out of the fluid ejection nozzles.

In one example, the mesofluidic plate may include a molded layer of moldable polymer, such as, for example, a cyclic olefin copolymer (COC) material. In another example the mesofluidic plate may include a patterned porous media. A protective film may be disposed between the die package and the mesofluidic plate. The protective film forms fluidic bypasses between the fluidic dies. In one example, the microfluidic device may include reagents disposed within the mesofluidic plate to react with a fluid introduced to the mesofluidic plate. The microfluidic device may also include a venting hole to vent air from the microfluidic device as fluid is introduced into the mesofluidic plate.

Examples described herein also provide a microfluidic device that includes a plurality of fluidic dies overmolded within an overmold material. The microfluidic device may also include a mesofluidic plate coupled to a fluid ejection side of the fluidic dies. The mesofluidic plate may include at least one mesofluidic channel formed therein to fluidically couple the fluidic dies.

The overmold material of the microfluidic device may include an epoxy mold compound (EMC). Further, the microfluidic device may include a fluid feed slot defined within the overmold material to fluidically couple a fluid source to the fluidic dies.

In one example, at least one of the fluidic dies may include a silicon layer that includes a fluid feed hole defined therein. The fluid feed hole may be fluidically coupled to the fluid feed slot. The fluidic dies may also include a nozzle layer coupled to the silicon layer. The nozzle layer may include fluid ejection nozzles formed in the nozzle layer and a fluid chamber formed in the nozzle layer. The fluid chamber fluidically couples the fluid feed slot to the fluid ejection nozzles via, for example, a fluid feed hole. The fluidic dies may also include an actuator within the fluid chamber to eject fluid from the fluidic die out the fluid ejection nozzles. The microfluidic device may include a protective film disposed between the die package and the mesofluidic plate. In one example, the protective film forms a fluidic bypass with respect to at least one of the fluidic dies.

Examples described herein also provide a method of fluidic transport. The method may include priming a first fluidic die of a plurality of fluidic dies embedded within an overmold material, and utilizing back pressure to restrict a fluid from exiting the first fluidic die and entering a mesofluidic plate coupled to a fluid ejection side of the fluidic dies. The mesofluidic plate includes at least one mesofluidic channel formed therein to fluidically couple the fluidic dies. The method may also include ejecting an amount of the fluid from the first fluidic die into the at least one mesofluidic channel of the mesofluidic plate with an actuator of the first fluidic die.

The fluid ejected into the at least one mesofluidic channel of the mesofluidic plate passively wicks to a second fluidic die. The method may also include reacting the fluid with reagents disposed within the at least one mesofluidic channel of the mesofluidic plate.

As used in the present specification and in the appended claims, the terms “meso-,” “mesoscale,” “mesofluidic,” or similar terms is meant to be understood broadly as any element that is between approximately 100 and 1,000 micrometers in size including solid elements and voids.

As used in the present specification and in the appended claims, the terms “micro-,” “microscale,” “microfluidic,” or similar terms is meant to be understood broadly as any element that is between approximately 10 and 100 micrometers in size including solid elements and voids.

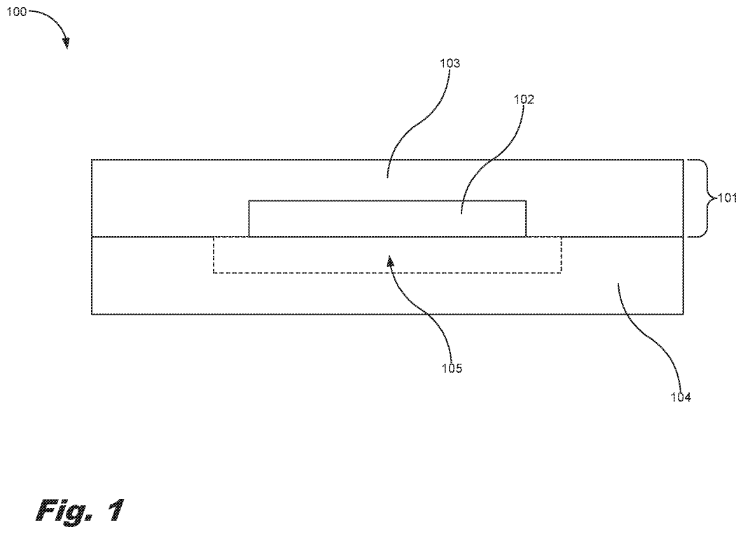

Turning now to the figures, FIG. 1 is a cross-sectional block diagram of a microfluidic device (100), according to an example of the principles described herein. The microfluidic device (100) may include a die package (101) including at least one fluidic die (102), and an overmold material (103) overmolding the fluidic die. The microfluidic device (100) may also include a mesofluidic plate (104) coupled to the die package (101). The mesofluidic plate (104) includes at least one mesofluidic channel (105) formed therein. In one example, the die package (101) of the microfluidic device (100) may include a plurality of fluidic die (102) within the overmold material (103). In this example, the mesofluidic channels (105) of the mesofluidic plate (104) fluidically couple the plurality of fluidic dies (102).

In one example, the overmold material (103) may include any material that may be molded around the fluidic die (102) including, for example, an epoxy mold compound (EMC). The overmold material (103) may be overmolded around multiple exterior surfaces of each fluidic die (102) included in the die package (101). In one example, a fluid ejection side of each of the fluidic die (102) may be left unobscured by the overmold material (103) to allow for fluid to be ejected by fluidic die (102).

The mesofluidic plate (104) may be made of any flexible material that allows for roll-to-roll processing of the mesofluidic plate (104) and allow for compliant adhesion to the die package (101). In one example, the mesofluidic plate (104) may include a molded layer of moldable polymer. The mesofluidic plate (104) may be formed through transfer molding. In one example, the mesofluidic plate (104) may include a cyclic olefin copolymer (COC) material.

In another example, the mesofluidic plate (104) may include a porous media that may be patterned to allow transfer of the fluids among the at least one fluidic die (102). In one example, the porous media may include a wax-infused media.

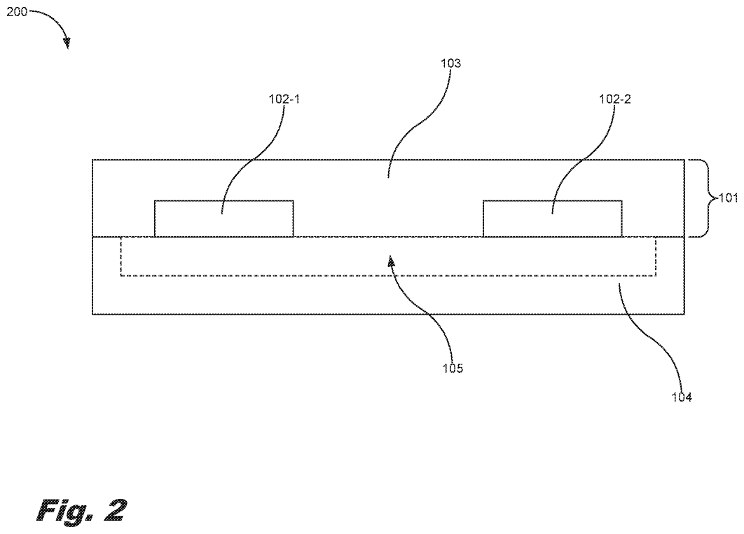

FIG. 2 is a cross-sectional block diagram of a microfluidic device (200), according to another example of the principles described herein. The example microfluidic device (200) of FIG. 2 includes a plurality of fluidic dies (102-1, 102-2, collectively referred to herein as 102) overmolded within the overmold material (103) within the die package (101). The mesofluidic plate (104) is included, and is coupled to a fluid ejection side of the fluidic dies (102). The mesofluidic plate (104), as in FIG. 1, includes at least one mesofluidic channel (105) formed therein to fluidically couple the plurality of fluidic dies (102-1, 102-2) so that fluid ejected from one of the fluidic dies (102-1) may be conveyed to another fluidic die (102-2) in order to allow the fluids to react or otherwise interact with one another.

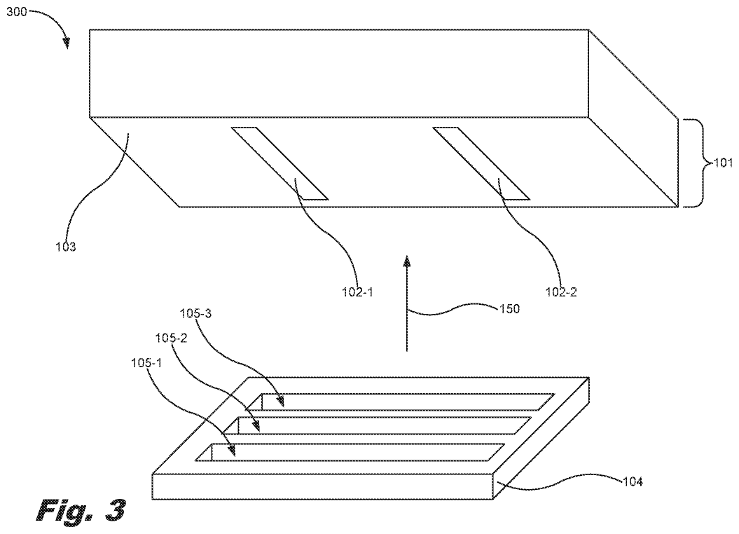

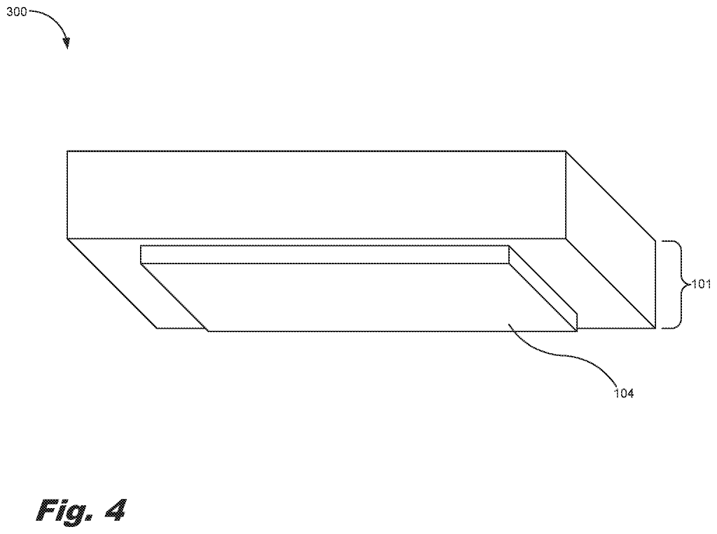

FIG. 3 is an exploded, isometric view of a microfluidic device (300), according to an example of the principles described herein. FIG. 4 is an isometric view of the microfluidic device (300) of FIG. 3, according to an example of the principles described herein. The microfluidic device (300) of FIG. 3 includes identical elements as presented herein in connection with FIGS. 1 and 2, and description of those elements may be had by referring to the descriptions of FIGS. 1 and 2. The fluidic dies (102-1, 102-2) are fluidically coupled to one another via a plurality of mesofluidic channels (105-1, 105-2, 105-3, collectively referred to herein as 105). The mesofluidic channels (105) may couple, for example, two fluidic die (102-1, 102-2), and may do so at any number of locations along a length of the fluidic die (102).

As depicted in FIGS. 3 and 4, the mesofluidic plate (104) is moved in the direction of arrow (150) and coupled to the die package (101). In one example, the mesofluidic plate (104) may be laminated to the die package (101). In this example, the mesofluidic plate (104) may be coupled to the die package (101) through heat, pressure, welding, via adhesives, or a combination thereof.

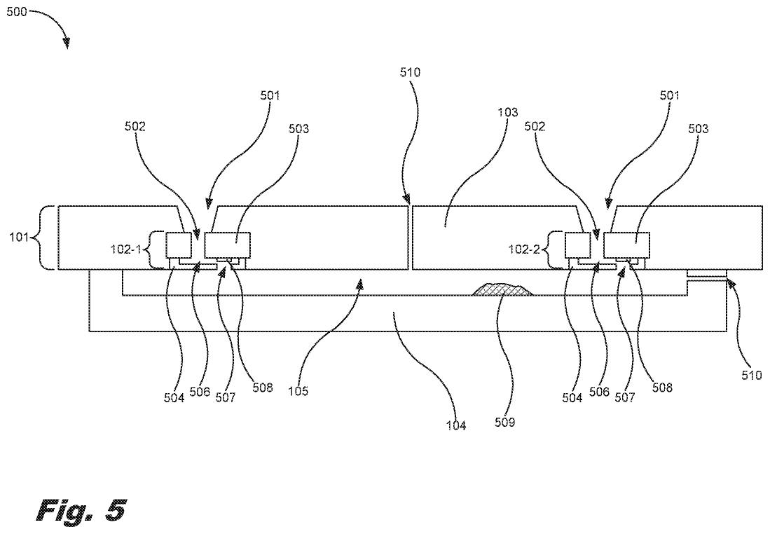

FIG. 5 is a cross-sectional view of a microfluidic device (500), according to an example of the principles described herein. The microfluidic device (500) of FIG. 5 may include a plurality of fluidic dies (102) embedded within the overmold material (103) as described herein. The mesofluidic plate (104) is laminated to the die package (101) such that the mesofluidic channel (105) extends past the fluidic dies (102) allowing for a lower tolerance between the mesofluidic plate (104) and the die package (101). This provides for a misalignment-tolerant assembly that, in turn, costs less to manufacture given the eased tolerances. During manufacture of a microfluidic device, tolerance with regard to alignment may be so low that misalignment may occur. However, because the present microfluidic devices utilize the mesofluidic plate (104), a relatively higher tolerance is allowed making manufacturing of the present microfluidic devices easier and more economical. For example, pick-and-place accuracy in manufacturing is not as demanding with the mesofluidic plates (104) described herein. Further, the tolerances provided in the mesofluidic plates (104) allow for shifts that occur during a molding process of the mesofluidic plates to not be as significant in the functioning of the mesofluidic plates, and thermal contraction or expansion that may occur in the mesofluidic plates (104) during operation will not affect the functioning of the mesofluidic plates (104).

A number of slots (501) may be defined in the overmold material (103) to allow a fluid such as an analyte to enter a fluid feed hole (502) defined in a silicon layer (503) of the fluidic dies (102). A fluid chamber (506) defined in a nozzle layer (504) of the fluidic dies (102) is fluidically coupled to the slots (501) and fluid feed holes (502). Each fluid chamber (506) may include an actuator (508) disposed therein to eject fluid from the fluid chamber (506) out of the fluidic die (102) through a nozzle (507) and into the mesofluidic channels (105) of the mesofluidic plate (104). In this manner, fluid entering the microfluidic device (500) from one side of the die package (101) may be introduced into the mesofluidic channels (105), and travel from one fluidic die (102) to a number of additional fluidic die (102) in order to react, mix, filter, dilute, separate, or heat the fluid, perform other chemical and physical processes on the fluid, or combinations thereof.

The fluid under test may prime the fluid chamber (506) of each of the fluidic die (102) via the slot (501) in the overmold material (103) and the fluid feed holes (502) defined in the silicon layer (503). The fluid may enter the fluid chamber (506) and is retained at the nozzle (507) and kept from entering the mesofluidic channel (105) by meniscus pressure, backpressure created upstream from the slot (501), or a combination thereof.

When a fluid is to be dispensed into the mesofluidic channel (105), the actuator (508) may be activated to jet the fluid out of, for example, the fluidic die (102-1) through a nozzle (507) and into the mesofluidic channels (105) of the mesofluidic plate (104). The mesofluidic channels (105) may fill up with the fluid as the fluid passively wicks along the mesofluidic channels (105). Eventually, the fluid will reach the second fluidic die (102-2), which the fluid primes passively by capillary action of the nozzles (507) of the second fluidic die (102-2).

In one example, the mesofluidic channels (105) of the mesofluidic plate (104) may include amounts of a reagent (509). These reagents (509) may include, for example, a polymerase chain reaction (PCR) mastermix. In another example, the reagents (509) may include chemicals that mix, filter, dilute, or heat the fluid, chemicals that separate chemical constituents of the fluid, chemicals that perform other chemical processes, or combinations of these. These reagents (509) may also include a gel that absorbs a fluid such as, for example, a hydrogel designed to swell upon absorbing the water. As the fluid wicks toward the second fluidic die (102-2), the fluid may reconstitute the reagents (509), which, in one example, may be in the form of a dry material that was pre-stored in the mesofluidic channels (105). The reagents (509) may also include, paraffin plugs, porous media, swelling hydrogels, surface-active beads or other materials that provide additional functionality to the microfluidic device.

In one example, the microfluidic device (500) may include a venting hole (510) to vent air from the mesofluidic channels (105) of the microfluidic device (500) as fluid is introduced into the mesofluidic plate (104). The venting hole (510) may be a dedicated venting hole as depicted in FIG. 5, or the slots (501) fluidically coupled to the fluidic dies (102) may serve as venting holes while the fluid travels from one fluidic die (102-1) to another fluidic die (102-2). In one example, a venting hole (510) may be formed in the mesofluidic plate (104) as depicted in FIG. 5.

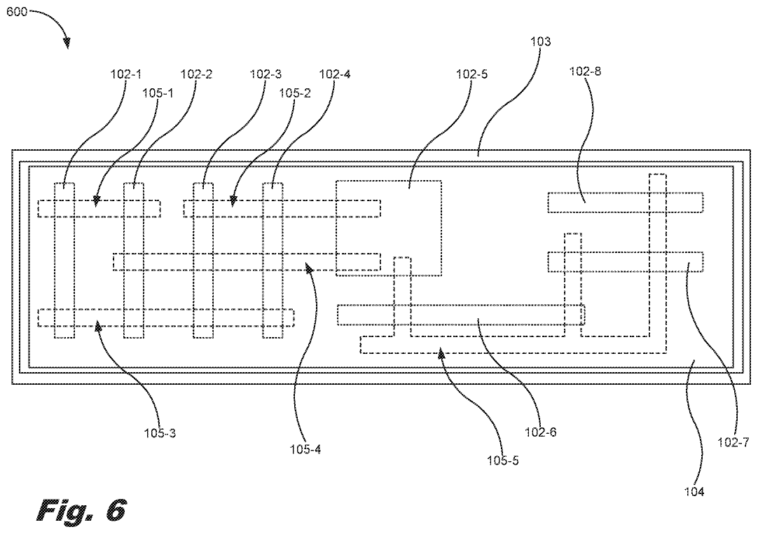

FIG. 6 is a bottom view of a microfluidic device (600), according to an example of the principles described herein. The microfluidic device (600) of FIG. 6 may include a plurality of fluidic die (102-1, 102-2, 102-3, 102-4, 102-5, 102-6, 102-7, 102-8) overmolded with the overmold material (103) to form the die package (FIG. 1, 101). As depicted in FIG. 6, the fluidic die (102) may have varying dimensions, and may be overmolded within the overmold material (103) at varying positions within the overmold material (103) and at varying orientations. In one example, the fluidic die (102) may each serve varying purposes, introduce different fluids into the microfluidic device (600), perform different functions, and combinations thereof.

Also, the mesofluidic plate (104) coupled to the die package (101) includes a plurality of mesofluidic channels (105-1, 105-2, 105-3, 105-4, 105-5) formed therein. The mesofluidic channels (105) may have any shape and orientation as defined within the mesofluidic plate (104). Further, as is the case with the example mesofluidic channel (105-5), the mesofluidic channels (105) may have branching channels extending from a common channel to couple fluidic die (102) to one another that are oriented within the overmold material (103) such that the mesofluidic channel (105-5) turns to couple those fluidic die (102). In examples where the microfluidic device (600) includes one fluidic die (102), the branching mesofluidic channel (105-5) may be used to fluidically couple two separate portions of the fluidic die (102). In FIG. 6, the fluidic die (102) are depicted with a different dashed line pattern than the mesofluidic channels (105) in order to distinguish the two types of elements.

In the example of FIG. 6, the first mesofluidic channel (105-1) fluidically couples the first fluidic die (102-1) and the second fluidic die (102-2). Further, the second mesofluidic channel (105-2) fluidically couples the third fluidic die (102-3), the fourth fluidic die (102-4), and the fifth fluidic die (102-5). The third mesofluidic channel (105-3) fluidically couples the first fluidic die (102-1), the second fluidic die (102-2), the third fluidic die (102-3), and the fourth fluidic die (102-4). The fourth mesofluidic channel (105-4) fluidically couples the second fluidic die (102-2), the third fluidic die (102-3), the fourth fluidic die (102-4), and the fifth fluidic die (102-5). Further, the fifth mesofluidic channel (105-5) fluidically couples the fifth fluidic die (102-5), the sixth fluidic die (102-6), the seventh fluidic die (102-7), and the eighth fluidic die (102-8) via a number of branching portions of the fifth mesofluidic channel (105-5). Although the fluidic die (102) and mesofluidic channels (105) are arranged as described here, the fluidic die (102) and the mesofluidic channels (105) may be arranged in any layout to achieve a desired function or series of processes.

At portions of the microfluidic device (600) where a fluidic die (102) and a mesofluidic channel (105) intersect, the fluids introduced into that fluidic die (102) may travel through the entirety of the mesofluidic channel (105) to a plurality of other fluidic die (102) and mesofluidic channels (105). For example, fluid introduced into the microfluidic device (600) through fluidic die (102-1) may travel through either mesofluidic channel (105-1) or mesofluidic channel (105-3) into fluidic die (102-2). Thereafter, a second fluid may be introduced into the microfluidic device (600) by fluidic die (102-2) and mixed with the fluid introduced by fluidic die (102-1). This mixed fluid may then be ejected by the second die (102-2) into, for example, mesofluidic channel (105-4) for further processing by other fluidic dies (102) and within other mesofluidic channels (105). In one example, each of the mesofluidic channels (105) may each include a number of reagents (509) disposed therein to effectuate different reactions as the fluids introduced into the microfluidic device (600) via the fluidic dies (102) enter the mesofluidic channels (105).

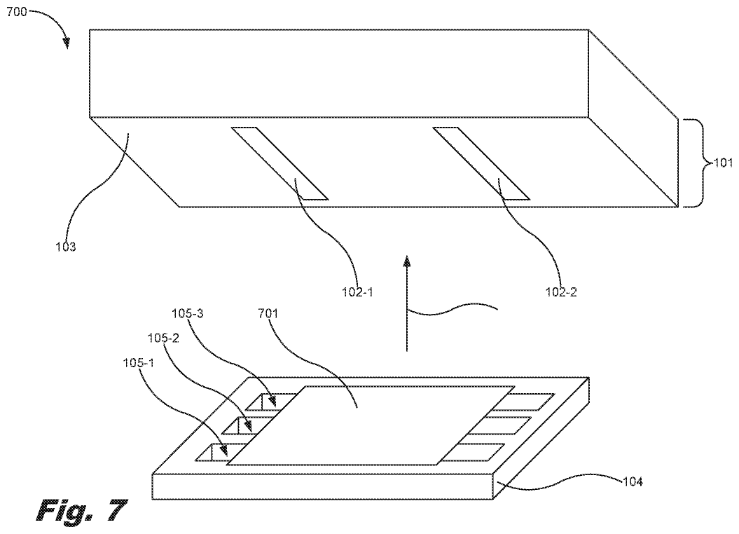

FIG. 7 is an exploded, isometric view of a microfluidic device (700), according to another example of the principles described herein. Those elements included in, for example, FIG. 3 are also identified in FIG. 7, and description regarding these elements is provided herein in connection with FIG. 3. The example of FIG. 7 includes a protective film (701). The protective film (701) may be disposed between the die package (101) and the mesofluidic plate (104), and forms a number of fluidic bypasses between the fluidic dies (102). The protective film (701) imbedded between the die package (101) and the mesofluidic plate (104) define interconnects in a third dimension between fluidic dies (102) that are not neighboring and in instances in which intermediary fluidic dies (102) are to be bypassed. In one example, the surface of the overmold material (103) may provide confinement of the fluid and act as a bypass instead of or in addition to the use of the protective film (701).

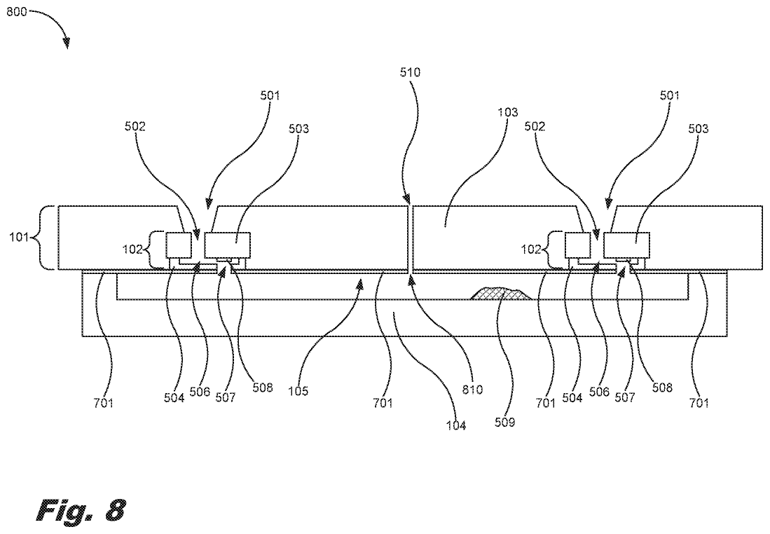

FIG. 8 is a cross-sectional view of a microfluidic device (800), according to an example of the principles described herein. Those elements included in, for example, FIG. 5 are also identified in FIG. 8, and description regarding these elements is provided herein in connection with FIG. 5. The example of FIG. 8 includes the protective film (701) described in connection with FIG. 7. The protective film (701) may include openings that are equal to or larger than a diameter of the nozzles (507) to allow for misalignment tolerances between the protective film (701) and the nozzles (507). Further, the protective film (701) may include an opening (810) that is equal to or larger than a diameter of the venting hole (510) and formed to align with the venting hole (510) to vent air from the mesofluidic channels (105) of the microfluidic device (500) as fluid is introduced into the mesofluidic plate (104).

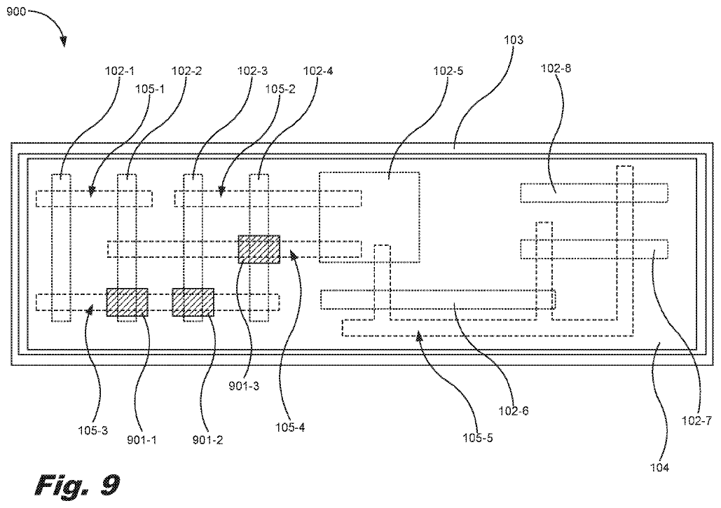

FIG. 9 is a bottom view of a microfluidic device (900), according to another example of the principles described herein. Those elements included in, for example, FIG. 6 are also identified in FIG. 9, and description regarding these elements is provided herein in connection with FIG. 6. The example of FIG. 9 includes sections of protective film (901-1, 901-2, 901-3, collectively referred to herein as 901) along portions of the mesofluidic channels (105) that intersect with the fluidic die (102). The protective films (901) exclude the fluidic die (102) at which the protective films (901) are located from ejecting fluid into the mesofluidic channel (105) and further prevent fluid already in the mesofluidic channel (105) from entering and interacting with the fluidic die (102). In this manner, the protective films (901) act as bypasses as they prevent interaction between the mesofluidic channels (105) and the fluidic die (102).

In FIG. 9, a first protective film (901-1) is placed at the intersection between the second fluidic die (102-2) and the third mesofluidic channel (105-3). Further, a second protective film (901-2) is placed at the intersection between the third fluidic die (102-3) and the third mesofluidic channel (105-3). In this manner, the first fluidic die (102-1) is fluidically coupled to the fourth fluidic die (102-4) via the third mesofluidic channel (105-3), but is prevented from being fluidically coupled to the second fluidic die (102-2) and the third fluidic die (102-3). Similarly, the second fluidic die (102-2), third fluidic die (102-3), and fifth fluidic die (102-5) are fluidically coupled to one another via the fourth mesofluidic channel (105-4), but the fourth fluidic die (102-4) is not due to the inclusion of a third protective film (901-3) disposed between the fourth mesofluidic channel (105-4) and the fourth fluidic die (102-4). In this manner, fluidic die (102) may be bypassed to prohibit interaction between fluids dispensed by the fluidic die (102) as desired or as intended for a design purpose.

In one example, and with reference to FIGS. 6 through 9, not every geometrical intersection between the fluidic die (102) and the mesofluidic channels (105) may forma physical fluidic connection. In some examples where the fluidic die (102) and the mesofluidic channels (105) intersect, the fluidic die (102) may not include nozzles (507), actuators (508), or even fluid chambers (506) at that location. In this example, fluid that may be dispensed from the fluidic die (102) is simply not able to be ejected into the mesofluidic channel (105) it intersects with. In one example, the fluidic die (102) may be designed in this manner to preclude the ejection of fluid into a mesofluidic channel (105), and may be used instead of or in addition to the protective film (701) included between the die package (101) and the mesofluidic plate (104).

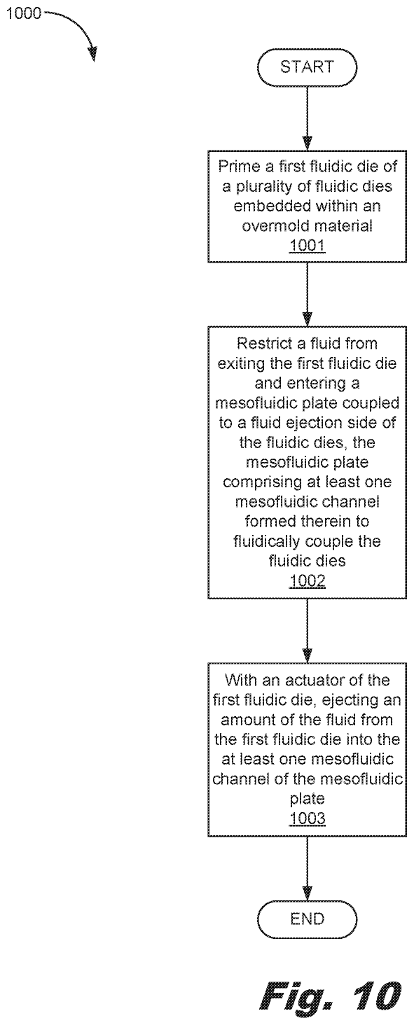

FIG. 10 is a flowchart (1000) showing a method of fluidic transport, according to an example of the principles described herein. The method (1000) of fluidic transport may include priming (block 1001) a first fluidic die (102-1) of a plurality of fluidic dies (102) embedded within an overmold material (103). A fluid may be restricted (block 1002) from exiting the first fluidic die (102-1) and entering a mesofluidic plate (104) coupled to a fluid ejection side of the fluidic dies (102). The mesofluidic plate (104) may include at least one mesofluidic channel (105) formed therein to fluidically couple the fluidic dies (102). The method may also include ejecting (block 1003), with an actuator (508) of the first fluidic die (102-1), an amount of the fluid from the first fluidic die (102-1) into the at least one mesofluidic channel (105) of the mesofluidic plate (104). The fluid ejected into the at least one mesofluidic channel (105) of the mesofluidic plate (104) passively wicks to a second fluidic die (102-2).

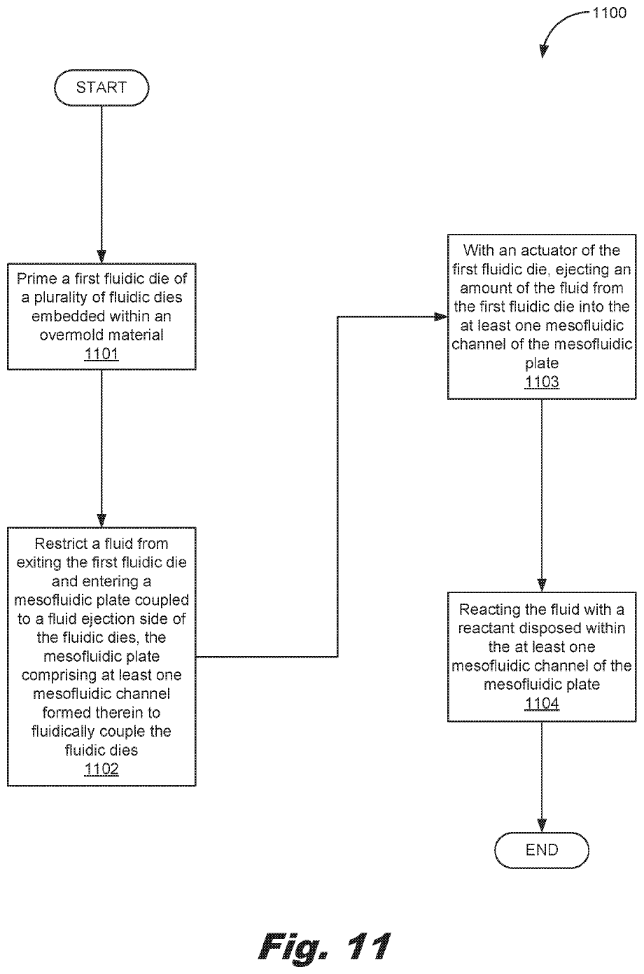

FIG. 11 is a flowchart showing a method (1100) of fluidic transport, according to another example of the principles described herein. The method (1100) of fluidic transport may include priming (block 1101) a first fluidic die (102-1) of a plurality of fluidic dies (102) embedded within an overmold material (103). A fluid may be restricted (block 1102) from exiting the first fluidic die (102-1) and entering a mesofluidic plate (104) coupled to a fluid ejection side of the fluidic dies (102). The mesofluidic plate (104) may include at least one mesofluidic channel (105) formed therein to fluidically couple the fluidic dies (102).

The method may also include ejecting (block 1103), with an actuator (508) of the first fluidic die (102-1), an amount of the fluid from the first fluidic die (102-1) into the at least one mesofluidic channel (105) of the mesofluidic plate (104). The fluid ejected into the at least one mesofluidic channel (105) of the mesofluidic plate (104) passively wicks to a second fluidic die (102-2). The method may further include reacting (block 1104) the fluid with a reagent (509) disposed within the at least one mesofluidic channel (105) of the mesofluidic plate (104).

The specification and figures describe a microfluidic device. The microfluidic device may include a die package. The die package may include at least one fluidic die and an overmold material overmolding the fluidic die. The microfluidic device may also include a mesofluidic plate coupled to the die package. The mesofluidic plate includes at least one mesofluidic channel formed therein to fluidically couple the fluidic die.

The microfluidic devices described herein may be quickly and inexpensively fabricated in different facilities to allow for different mesofluidic plates to be manufactured with a wide range of layouts to increase the function and versatility of the microfluidic devices into which the mesofluidic plates are incorporated. The reagents or other materials can be dispensed in the mesofluidic channels and prepared using special conditions such as, for example, a low relative humidity. The die package and the mesofluidic plate are coupled to one another at a final assembly point, which simplifies manufacturing logistics. Further, because the dimensions of the mesofluidic channels are relatively larger than microfluidic channels that include die-to-die misalignment tolerances on the order of 5-20 μm or less, the manufacturing of the present mesofluidic devices provides for a more tolerant manufacturing process. Further, these tolerances also ensure functioning of the microfluidic device even with thermal contraction and expansion of the mesofluidic plate. Thus, the interconnect technology described herein is misalignment tolerant, which makes the microfluidic device relatively more practical. Further, in addition to providing interconnects between fluidic die, the mesofluidic channels in the mesofluidic plate may be utilized to store dry reagents, paraffin plugs, porous media, swelling hydrogels, surface-active beads or other materials used in device operation.

The preceding description has been presented to illustrate and describe examples of the principles described. This description is not intended to be exhaustive or to limit these principles to any precise form disclosed. Many modifications and variations are possible in light of the above teaching.

What is claimed is:

1. A microfluidic device, comprising:
a die package comprising:
at least one fluidic die; and
an overmold material overmolding the fluidic die;
a mesofluidic plate coupled to the die package, the mesofluidic plate comprising at least one mesofluidic channel formed therein.

2. The microfluidic device of claim 1, wherein the at least one fluidic die comprises:
a silicon layer;
a fluid feed hole defined in the silicon layer;
a nozzle layer coupled to the silicon layer;
fluid ejection nozzles formed in the nozzle layer;
a fluid chamber formed in the nozzle layer, the fluid chamber fluidically coupling the fluid feed hole to the fluid ejection nozzles; and
an actuator within the fluid chamber to eject fluid from the fluidic die out the fluid ejection nozzles.

3. The microfluidic device of claim 1, wherein the mesofluidic plate comprises a molded layer of moldable polymer material.

4. The microfluidic device of claim 1, wherein the mesofluidic plate comprises a patterned porous media.

5. The microfluidic device of claim 1, comprising a protective film disposed between the die package and the mesofluidic plate, the protective film forming fluidic bypasses between the fluidic dies.

6. The microfluidic device of claim 1, comprising reagents disposed within the mesofluidic plate to react with a fluid introduced to the mesofluidic plate.

7. The microfluidic device of claim 1, comprising a venting hole to vent air from the microfluidic device as fluid is introduced into the mesofluidic plate.

8. A microfluidic device, comprising:
a plurality of fluidic dies overmolded within an overmold material;
a mesofluidic plate coupled to a fluid ejection side of the fluidic dies, the mesofluidic plate comprising at least one mesofluidic channel formed therein to fluidically couple the fluidic dies.

9. The microfluidic device of claim 8, wherein the overmold material comprises an epoxy mold compound (EMC).

10. The microfluidic device of claim 8, comprising a fluid feed slot defined within the overmold material to fluidically couple a fluid source to the fluidic dies.

11. The microfluidic device of claim 10, wherein at least one of the fluidic dies comprises:
a silicon layer comprising a fluid feed hole defined therein, the fluid feed hole being fluidically coupled to the fluid feed slot;
a nozzle layer coupled to the silicon layer, the nozzle layer comprising:
fluid ejection nozzles formed in the nozzle layer, and
a fluid chamber formed in the nozzle layer, the fluid chamber fluidically coupling the fluid feed slot to the fluid ejection nozzles; and
an actuator within the fluid chamber to eject fluid from the fluidic die out the fluid ejection nozzles.

12. The microfluidic device of claim 8, comprising a protective film disposed between the die package and the mesofluidic plate, the protective film forming a fluidic bypass with respect to at least one of the fluidic dies.

13. A method of fluidic transport, comprising:
priming a first fluidic die of a plurality of fluidic dies embedded within an overmold material;
restricting a fluid from exiting the first fluidic die and entering a mesofluidic plate coupled to a fluid ejection side of the fluidic dies, the mesofluidic plate comprising at least one mesofluidic channel formed therein to fluidically couple the fluidic dies;
with an actuator of the first fluidic die, ejecting an amount of the fluid from the first fluidic die into the at least one mesofluidic channel of the mesofluidic plate.

14. The method of claim 13, wherein the fluid ejected into the at least one mesofluidic channel of the mesofluidic plate passively wicks to a second fluidic die.

15. The method of claim 13, comprising reacting the fluid with a reagent disposed within the at least one mesofluidic channel of the mesofluidic plate.
